(19) United States
(12) Patent Application Publication
(10) Pub. No.: US 2006/0091558 A1
(43) Pub. Date: May 4, 2006

(54) Circuitized substrate with trace embedded inside ground layer

(76) Inventors: Yao-Ting Huang, Kaoshiung (TW); Shih-Ching Chang, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/264,000

(22) Filed: Nov. 2, 2005

(30) Foreign Application Priority Data
Nov. 3, 2004 (TW) 093133482

(51) Int. Cl. H01L 23/48

(52) U.S. Cl. 257/774

(57) ABSTRACT

A circuitized substrate with trace embedded inside ground layer mainly comprises a trace layer, a first dielectric layer, a ground layer, a second dielectric layer, and at least one embedded conductive trace. The embedded conductive trace is located between the first dielectric layer and the second dielectric layer. The embedded conductive trace is hidden inside a hollow portion of the ground layer, and is electrically insulated from the ground layer. Therefore, by utilizing the embedded conductive trace, the traces of the trace layer can be decreased and the product yield can be improved.

### BACKGROUND OF THE INVENTION

1. Field of the Invention

The present invention relates to a circuitized substrate for a semiconductor package structure, and more particularly, to a circuitized substrate with trace embedded inside ground layer, so as to facilitate a high density alignment of multiple lines of connecting fingers.

2. Description of the Related Art

Recently, in the manufacturing process of a semiconductor package, a circuitized substrate is commonly used as a carrier for a semiconductor chip. The circuitized substrate comprises a plurality of trace layers and a plurality of dielectric layers, which has the advantage of compact wiring.

The conventional circuitized substrate for semiconductor package structure is double-sided electrically conductive, such as plastic ball grid array (PBGA) package substrate. An upper surface of the circuitized substrate is formed with a plurality of connecting fingers to which a chip is electrically connected, and a lower surface of the circuitized substrate is formed with a plurality of the external pads on which a plurality of solder balls are disposed. Referring to FIG. 1, in a conventional semiconductor package structure, a chip 110 is disposed on an upper surface 201 of a circuitized substrate 200. The chip 110 is electrically connected to the circuitized substrate 200 through a plurality of bonding wires 120. The chip 110 and the bonding wires 120 are encapsulated by a molding compound 130. A plurality of solder balls 140 are disposed on a lower surface 202 of the circuitized substrate 200. In such a conventional semiconductor package structure, the chip 110 is electrically connected to the circuitized substrate 200 through the bonding wires 120, and then electrically connected to the exterior through the solder balls 140 of the lower surface 202. For the increasing I/O pads formed on the chip, a high density alignment, for example, staggered, tri-tier or quad-tier alignment, of connecting fingers should be disposed on the upper surface 201 of the circuitized substrate 200 and the high-density alignment of connecting fingers are kept with a predetermined fine finger pitch for the connection of the bonding wires 120.

Referring to FIGS. 2A, 2B and 3, the circuitized substrate 200 comprises a first trace layer 210, a ground layer 220, a power layer 230, a second trace layer 240 and a plurality of dielectric layers 250. The dielectric layers 250 are disposed between the first trace layer 210, the ground layer 220, the power layer 230 and the second trace layer 240. The first trace layer 210 is formed on the upper surface 201 of the circuitized substrate 200. The second trace layer 240 is formed on the lower surface 202 of the circuitized substrate 200. A plurality of via holes 260 pass from the upper surface 201 to the lower surface 202. The first trace layer 210 comprises a plurality of traces 211, 212, a plurality of first line connecting fingers 213 and a plurality of second line connecting fingers 214, wherein the traces 211 are connected to the first line connecting fingers 213, while the traces 212 are connected to the second line connecting fingers 214. The traces 211, 212 can also be electrically connected to a plurality of connecting ball pads 241 of the second trace layer 240 through the corresponding via holes 260. The connecting ball pads 241 are used for being disposed with the solder balls 140, as shown in FIG. 1, so as to achieve external electrical connection. As shown in FIGS. 2A and 2B, a solder mask 270 is formed on the upper surface 201 of the circuitized substrate 200 and shields the first trace layer 210, while another solder mask 280 is formed on the lower surface 202 of the circuitized substrate 200 and shields the second trace layer 240. Referring to FIG. 3 again, in the first trace layer 210, the first line connecting fingers 213 are exposed at a first opening 271 of the solder mask 270, while the second line connecting fingers 214 are exposed at a plurality of the second opening 272 of the solder mask 270. Referring to FIGS. 1 and 3 again, because the first line connecting fingers 213 and the second line connecting fingers 214 are in a staggered alignment, and the second line connecting fingers 214 are more proximate to a die bond area 201a of the circuitized substrate 200 than the first line connecting fingers 213, and the traces 212 for connecting the second line connecting fingers 214 are exposed at the first opening 271, the exposed parts of the traces 212 will be subjected to oxidation. Because the traces 211, 212 are densely aligned on the first trace layer 210, which increases the difficulty of tracing, the yield of the circuitized substrate 200 decreases. Furthermore, the dimension of the first line connecting fingers 213 and the second line connecting fingers 214 is larger than the width of the traces 212, so while the circuitized substrate 200 is tested, an automatic substrate checking machine (not shown) will easily mistake the exposed traces 212 to be the unqualified connecting fingers, such that errors and difficulties occur during the detection of the circuitized substrate 200.

A “substrate for package” is disclosed in ROC (Taiwan) Patent Publication No. 594951, in which a plurality of first bond fingers and a plurality of second bond fingers are aligned at the front side of a substrate and the outside of a chip carrier by surrounding the chip carrier. The second bond fingers are farther away from the chip carrier than the first bond fingers, and a plurality of the first through holes and a plurality of second through holes are respectively disposed at the outside of the first bond fingers and the second bond fingers. Therefore, this alignment of the first and second bond fingers and the first and second through holes may result in the over-dense traces, wherein it is inevitable that a plurality of the first electrical traces for connecting the first bond fingers to the first through holes pass through the adjacent second bond fingers, and the second bond fingers are too dense to form respective solder mask openings. Thus, when the first bond fingers are exposed at a solder mask opening of large dimension, a part of the first electrical traces may also be exposed.

Consequently, there is an existing need for a circuitized substrate with trace embedded inside ground layer to solve the above-mentioned problems.

### SUMMARY OF THE INVENTION

The object of the present invention is to provide a circuitized substrate with trace embedded inside ground layer. The circuitized substrate comprises a trace layer, a first dielectric layer, a ground layer, a second dielectric layer and at least one embedded conductive trace. The trace layer is disposed on the first dielectric layer; the embedded conductive trace is disposed between the first dielectric layer and the second dielectric layer; and the embedded conductive trace is formed in a hollow portion of the ground layer and is electrically insulated from the ground layer. The embedded conductive trace is electrically connected to the trace layer, to replace part of the traces of trace layer, so as to facilitate the high-density alignment of a plurality of connecting fingers of the trace layer, and eliminate difficulties in the manufacturing process caused by the over density alignment of the traces of the trace layer, thereby improving the product yield.

Another object of the present invention is to provide a circuitized substrate with trace embedded inside ground layer. At least one embedded conductive trace is formed in a hollow portion of a ground layer, and the embedded conductive trace is electrically connected to at least one connecting finger of a trace layer through suitable via holes. Therefore, the number of traces of the trace layer can be reduced and a high-density alignment of multiple lines of the connecting fingers can be achieved on the trace layer.

Still another object of this invention is to provide a circuitized substrate with trace embedded inside ground layer. A trace layer comprises a plurality of traces, a plurality of first line connecting fingers and at least one second line connecting finger. A solder mask is formed on a trace layer to shield the traces. The solder mask is provided with an opening to expose the first line connecting fingers. At least one embedded conductive trace formed on the ground layer is electrically connected to the second line connecting fingers, without passing through the opening of the solder mask, thus avoiding the risk of exposing the traces.

The circuitized substrate with trace embedded inside ground layer according to this invention comprises a first trace layer, a first dielectric layer, a ground layer, a second dielectric layer and at least one embedded conductive trace. The first dielectric layer is disposed below the first trace layer. The ground layer is disposed below the first dielectric layer. The ground layer comprises at least one hollow portion. The second dielectric layer is disposed below the ground layer; the embedded conductive trace is disposed between the first dielectric layer and the second dielectric layer; and the embedded conductive trace is disposed in the hollow portion of the ground layer and is electrically insulated from the ground layer. The trace layer comprises a plurality of connecting fingers that can be aligned in multiple lines, in which at least one connecting finger is electrically connected to the embedded conductive trace through a via hole.

### BRIEF DESCRIPTION OF THE DRAWINGS

FIG. 1 is a schematic sectional view of a conventional semiconductor package structure;

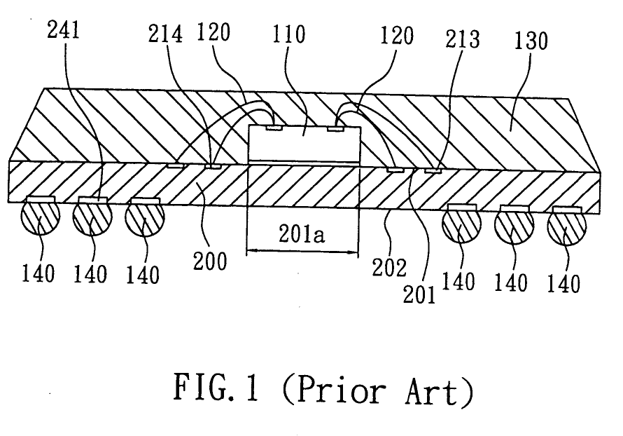

FIGS. 2A to 2B are schematic sectional views of the circuitized substrate suitable for the conventional semiconductor package structure;

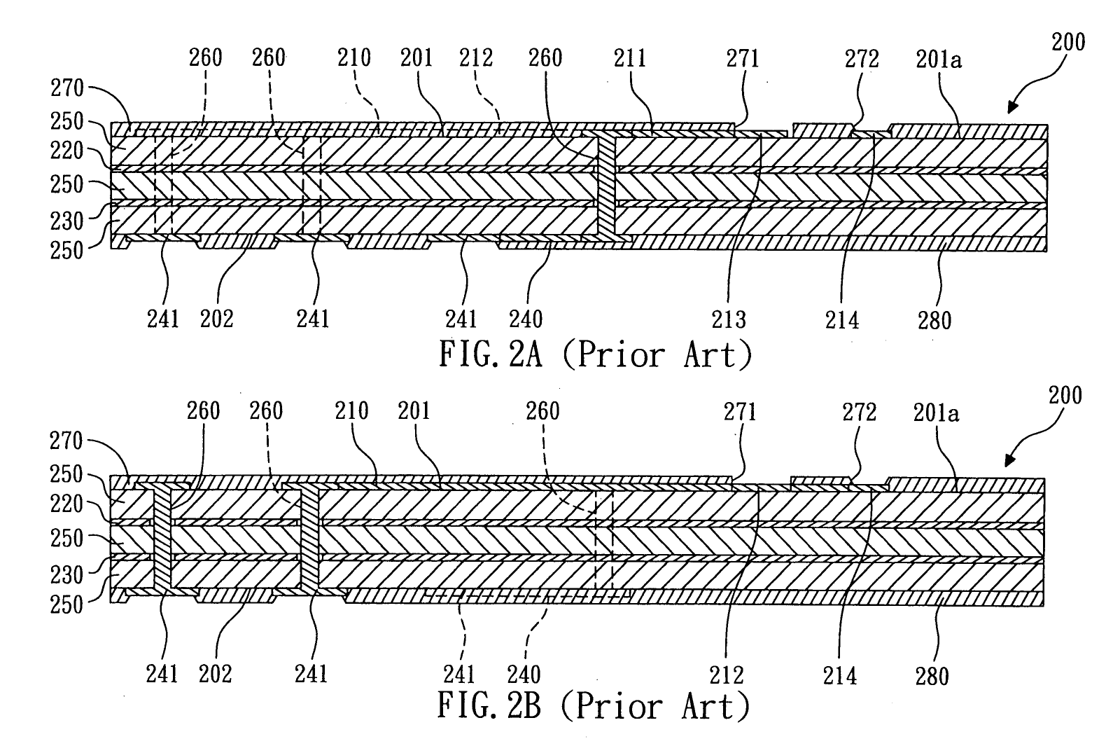

FIG. 3 is a schematic partial view of the upper surface of the conventional circuitized substrate;

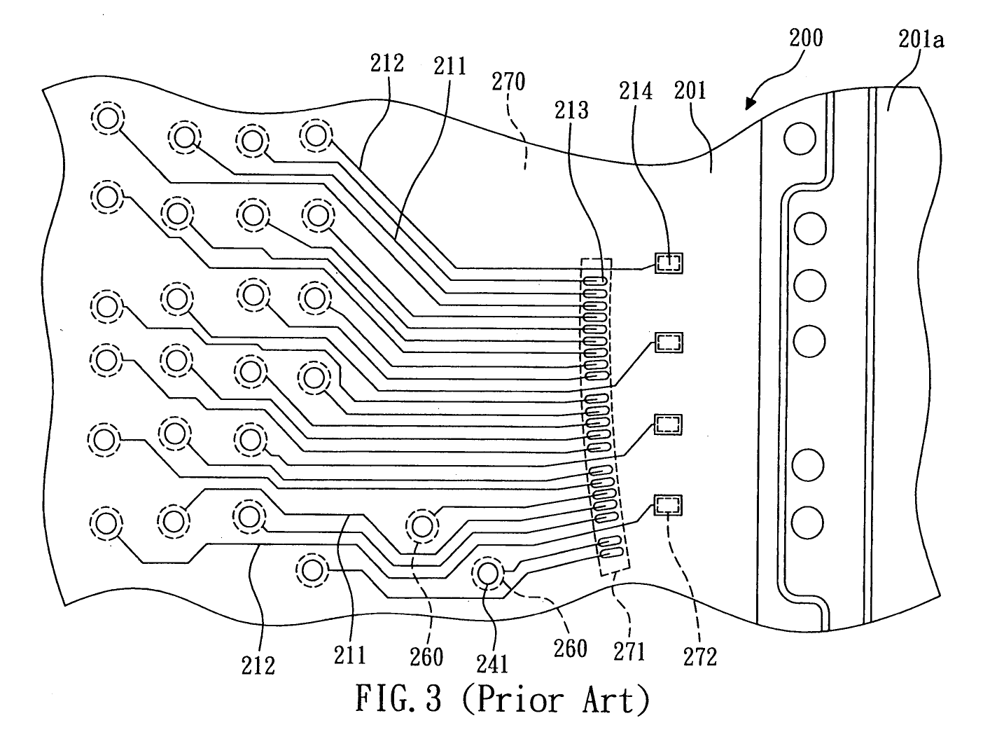

FIG. 4 is a schematic partial sectional view of a circuitized substrate with trace embedded inside ground layer according to an embodiment of the invention;

FIG. 5 is a schematic partial view of the upper surface of the circuitized substrate according to the embodiment of the invention; and

FIG. 6 is a schematic partial view of the ground layer of the circuitized substrate at the embedded conductive trace according to the embodiment of the invention.

### DETAILED DESCRIPTION OF THE INVENTION

The present invention will be illustrated with the following embodiments in accordance with the accompanying drawings.

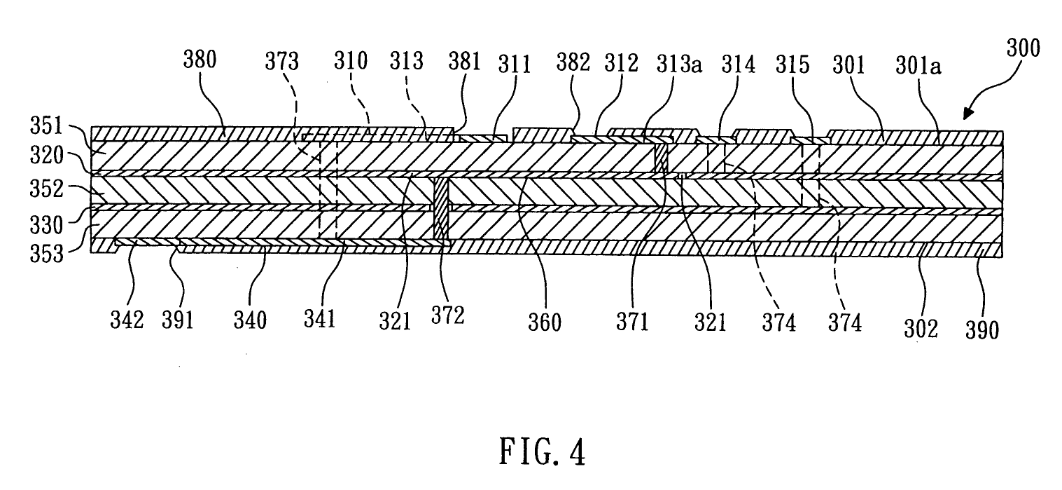

Referring to FIG. 4, according to an embodiment of this invention, a circuitized substrate 300 with trace embedded inside ground layer comprises an upper surface 301 and a lower surface 302. The circuitized substrate 300 is formed by stacking a plurality of patterned trace layers and a plurality of dielectric layers. In this embodiment, the patterned trace layers can be a first trace layer 310, a ground layer 320, a power layer 330 and a second trace layer 340 in sequence. The dielectric layers are a first dielectric layer 351, a second dielectric layer 352 and a third dielectric layer 353 in sequence. The first dielectric layer 351 is used to separate the first trace layer 310 from the ground layer 320. The second dielectric layer 352 is used to separate the ground layer 320 from the power layer 330. The third dielectric layer 353 is used to separate the power layer 330 from the second trace layer 340. In this embodiment, the first trace layer 310 is formed on an upper surface 301 of the circuitized substrate 300, while the second trace layer 340 is formed on a lower surface 302 of the circuitized substrate 300. The circuitized substrate 300 further comprises a plurality of embedded conductive traces 360 inside the ground layer 320 and disposed between the first dielectric layer 351 and the second dielectric layer 352. Preferably, technologies such as etching can be used to pattern the ground layer 320, so as to facilitate forming the embedded conductive traces 360.

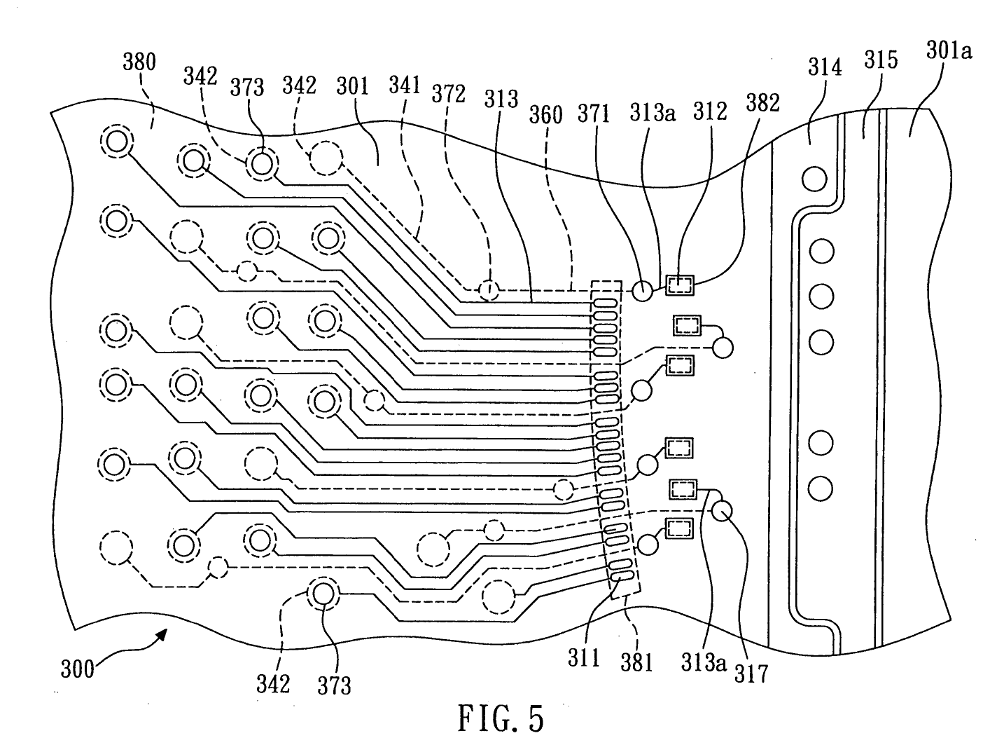

Referring to FIGS. 4 and 5, the first trace layer 310 comprises a plurality of first line connecting fingers 311, a plurality of second line connecting fingers 312 and a plurality of traces 313, 313a, in which the traces 313 are connected to the first line connecting fingers 311, while the traces 313a are connected to the second line connecting fingers 312. In this embodiment, the upper surface 301 of the circuitized substrate 300 is defined with a die bond area 301a at the center of the circuitized substrate 300. The second line connecting fingers 312 of the first trace layer 310 are disposed more interior than the first line connecting fingers 311 and thus the second line connecting fingers 312 are closer to the die bond area 301a.

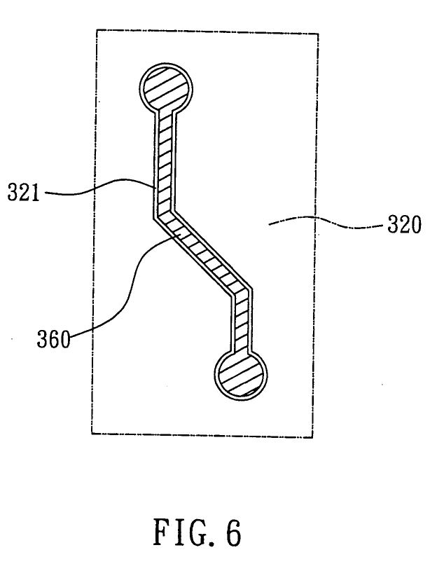

As shown in FIG. 4, the first dielectric layer 351 is disposed below the first trace layer 310, and the ground layer 320 is disposed below the first dielectric layer 351. The ground layer 320 can be a metal layer, such as a copper layer, for connecting to ground. As shown in FIG. 6, in this embodiment, the ground layer 320 can be formed with a plurality of hollow portions 321 and the embedded conductive traces 360 by selectivity etching. The embedded conductive traces 360 are formed in the hollow portions 321 of the ground layer 320 and are electrically insulated from the ground layer 320.

Referring to FIG. 4 again, the second dielectric layer 352 is disposed below the ground layer 320, in order to electrically insulate the ground layer 320 from the power layer 330. The third dielectric layer 353 is disposed between the power layer 330 and the second trace layer 340. In this embodiment, the second trace layer 340 and the first trace layer 310 are used for the electrical conduction of the chips (not shown). The second trace layer 340 comprises a plurality of traces 341 and a plurality of connecting ball pads 342, with the traces 341 connected to the connecting ball pads 342.

Referring to FIGS. 4 and 5, in this embodiment, the circuitized substrate 300 further comprises a plurality of first via holes 371, a plurality of second via holes 372 and a plurality of third via holes 373. An electroplated coating layer (not shown) for electrical conduction is formed in the first via holes 371, the second via holes 372 and the third via holes 373, so as to electrically connect the traces of different trace layers. The first via holes 371 pass from the upper surface 301 to the ground layer 320, so as to electrically connect the traces 313a of the first trace layer 310 and the embedded conductive traces 360. The second via holes 372 pass from the ground layer 320 to the lower surface 302, so as to electrically connect the embedded conductive trace 360 and the traces 341 of the second trace layer 340. In this embodiment, the first via holes 371 and the second via holes 372 are blind vias. Referring to FIG. 4 again, the third via holes 373 pass from the upper surface 301 to the lower surface 302, so as to electrically connect the traces 313 of the first trace layer 310 to the traces 341 of the second trace layer 340.

Furthermore, a first solder mask 380 is formed on the upper surface 301 of the circuitized substrate 300 so as to shield and protect the traces 313 of the first trace layer 310. A second solder mask 390 is formed on the lower surface 302 of the circuitized substrate 300 to shield and protect the traces 341 of the second trace layer 340, so as to avoid short-circuit caused by the exposed traces. Referring to FIGS. 4 and 5 again, the first solder mask 380 can be formed with a first opening 381 and a plurality of second openings 382 through exposure and development. The first opening 381 exposes the first line connecting fingers 311, and the second openings 382 expose the corresponding second line connecting fingers 312. Because the embedded conductive traces 360 connected to the second line connecting fingers 312 through the first via holes 371 are formed in the hollow portion 321 (FIG. 6) of the ground layer 320, it is unnecessary for the embedded conductive traces 360 to pass through the first opening 381 of the solder mask 380, thereby avoiding the risk of exposing the traces. Referring to FIG. 4, the solder mask 390 is formed with a plurality of connecting ball pad openings 391 to expose the connecting ball pads 342, so as to facilitate the arrangement of a plurality of solder balls (not shown).

Referring to FIGS. 4 and 5, the first trace layer 310 further comprises a ground ring 314 and a power ring 315 on the upper surface 301 of the circuitized substrate 300. Both of the ground ring 314 and the power ring 315 surround the die bond area 301a, and can be electrically connected to the traces 341 of the second trace layer 340 through a plurality of through holes 374 in the circuitized substrate 300.

In the above-mentioned circuitized substrate 300, the embedded conductive traces 360 are disposed between the first dielectric layer 351 and the second dielectric layer 352. The embedded conductive traces 360 are formed in the hollow portion 321 of the ground layer 320 and electrically insulated from the ground layer 320. The embedded conductive traces 360 are electrically connected to the second line connecting fingers 312 of the first trace layer 310 through the first via holes 371, so as to replace part of the traces 313a of the first trace layer 310, and thus it is unnecessary for the embedded conductive traces 360 to pass through the first line connecting fingers 311. Therefore, it facilitates the high-density arrangement of the first line connecting fingers 311 and the second line connecting fingers 312, and prevents an over-density arrangement of the traces 313, thereby avoiding the traces exposed at the first opening 381.

While an embodiment of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A circuitized substrate with trace embedded inside ground layer, comprising:
a first trace layer;
a first dielectric layer disposed below the first trace layer;
a ground layer disposed below the first dielectric layer, the ground layer comprising at least one hollow portion;
a second dielectric layer disposed below the ground layer; and
at least one embedded conductive trace disposed between the first dielectric layer and the second dielectric layer, the embedded conductive trace formed in the hollow portion of the ground layer and electrically insulated from the ground layer.

2. The circuitized substrate with trace embedded inside ground layer according to claim 1, wherein the first trace layer comprises a plurality of first line connecting fingers and at least one second line connecting finger, wherein the second line connecting finger is electrically connected to the embedded conductive trace through a first via hole.

3. The circuitized substrate with trace embedded inside ground layer according to claim 2, wherein the first via hole is a blind via.

4. The circuitized substrate with trace embedded inside ground layer according to claim 2, wherein the first trace layer further comprises a plurality of traces for connecting the first line connecting fingers.

5. The circuitized substrate with trace embedded inside ground layer according to claim 4, further comprising a solder mask formed on the first trace layer and the first dielectric layer to cover the traces.

6. The circuitized substrate with trace embedded inside ground layer according to claim 5, wherein the solder mask has a first opening for exposing the first line connecting fingers.

7. The circuitized substrate with trace embedded inside ground layer according to claim 6, wherein the solder mask further comprises a second opening for exposing the second line connecting finger.

8. The circuitized substrate with trace embedded inside ground layer according to claim 2, wherein the circuitized substrate is defined with a die bond area, the second line connecting fingers of the first trace layer being more interior than the first line connecting fingers, thus more closer to the die bond area.

9. The circuitized substrate with trace embedded inside ground layer according to claim 1, further comprising a power layer disposed below the second dielectric layer.

10. The circuitized substrate with trace embedded inside ground layer according to claim 9, further comprising a third dielectric layer and a second trace layer, the third dielectric layer being disposed between the power layer and the second trace layer.

11. The circuitized substrate with trace embedded inside ground layer according to claim 1, further comprising a second trace layer disposed below the second dielectric layer.

12. The circuitized substrate with trace embedded inside ground layer according to claim 11, further comprising a plurality of second via holes electrically connecting the embedded conductive trace and the second trace layer.

13. The circuitized substrate with trace embedded inside ground layer according to claim 11, further comprising a plurality of the third via holes electrically connecting the first trace layer and the second trace layer.

14. The circuitized substrate with trace embedded inside ground layer according to claim 11, wherein the second trace layer comprises a plurality of connecting ball pads.
